(19) United States
(12) Patent Application Publication
(10) Pub. No.: US 2015/0129029 A1
(43) Pub. Date: May 14, 2015

(54) Glass Frit, Composition for Solar Cell Electrodes Comprising the Same, and Electrode Fabricated Using the Same

(71) Applicant: Samsung SDI Co., Ltd., Yongin-si (KR)

(72) Inventors: Young Wook CHOI, Uiwang-si (KR); Dong Suk KIM, Uiwang-si (KR); Ji Youn LEE, Uiwang-si (KR)

(21) Appl. No.: 14/487,207

(22) Filed: Sep. 16, 2014

(30) Foreign Application Priority Data
Nov. 12, 2013 (KR) 10-2013-0137228

(51) Int. Cl. C03C 8/18; H01L 31/0224; H01B 1/16

(52) U.S. Cl. CPC C03C 8/18; H01B 1/16; H01L 31/022425
USPC 136/256; 501/19; 252/514

(57) ABSTRACT

Disclosed herein are a glass frit and a composition for solar cell electrodes including the same. The glass frit includes lead oxide (PbO) and boron oxide (B₂O₃) in a weight ratio of lead oxide to boron oxide of about 1:0.075 to about 1:1, wherein a mixture of the glass frit and aluminum (Al) powder in a weight ratio of about 1:1 exhibits a phase transition peak in the range of about 400° C. to about 650° C. on a cooling curve obtained via TG-DTA analysis, measured after heating the mixture to 900° C. at a heating rate of 20° C./min, holding for ten minutes, followed by cooling the mixture at a cooling rate of 10° C. The composition can provide stable efficiency given varying surface resistance and minimize adverse influence on a p-n junction.

### CROSS-REFERENCE TO RELATED APPLICATION

This application claims priority under 35 USC Section 119 to and the benefit of Korean Patent Application No. 10-2013-0137228, filed Nov. 12, 2013, the entire disclosure of which is incorporated herein by reference.

### FIELD OF THE INVENTION

The present invention relates to a glass frit, a composition for solar cell electrodes comprising the same, and electrodes fabricated using the same.

### BACKGROUND

Solar cells may be used to generate electricity through the photovoltaic effect of a p-n junction that converts photons of sunlight into electricity. In the solar cell, front and rear electrodes may be respectively formed on upper and lower surfaces of a substrate, e.g., a semiconductor wafer, etc., with the p-n junction. The photovoltaic effect at the p-n junction is induced by sunlight entering the semiconductor wafer and electrons generated by the photovoltaic effect at the p-n junction provide electric current to the outside through the electrodes. The electrodes of the solar cell are formed on the wafer by applying, patterning, and baking an electrode composition.

Continuous reduction in emitter thickness to improve solar cell efficiency can cause shunting which can deteriorate solar cell performance. In addition, solar cells have been gradually increased in area to achieve higher efficiency. In this case, however, there can be a problem of efficiency deterioration due to increase in solar cell contact resistance.

In addition, research on using n-type substrates, which are high-purity wafers, is being actively carried out to prevent deterioration in open voltage due to surface recombination by impurities within a wafer.

Therefore, there is a need for a composition for solar cell electrodes that can minimize adverse influence on a p-n junction given varying substrates, such as p-type substrates, n-type substrates and the like to secure stability of the p-n junction, thereby improving solar cell efficiency.

### SUMMARY

Exemplary embodiments of the present invention relate to a glass frit. The glass frit includes lead oxide (PbO) and boron oxide (B₂O₃) in a weight ratio of lead oxide to boron oxide of about 1:0.075 to about 1:1, wherein a mixture of the glass frit and aluminum (Al) powder in a weight ratio of about 1:1 exhibits a phase transition peak in the range of about 400° C. to about 650° C. on a cooling curve obtained via TG-DTA analysis, measured after heating the mixture to 900° C. at a heating rate of 20° C./min, holding for ten minutes, followed by cooling the mixture at a cooling rate of 10° C./min.

The mixture may exhibit a phase transition peak in the range of about 250° C. to about 300° C. on a cooling curve obtained via TG-DTA analysis, measured after heating the mixture to 600° C. at a heating rate of 20° C./min, holding for ten minutes, followed by cooling the mixture at a cooling rate of 10° C./min.

The glass frit may include at least one of bismuth oxide, silicon oxide, zinc oxide, lead oxide, tellurium oxide, tungsten oxide, magnesium oxide, strontium oxide, molybdenum oxide, barium oxide, nickel oxide, copper oxide, sodium oxide, cesium oxide, titanium oxide, tin oxide, indium oxide, vanadium oxide, cobalt oxide, zirconium oxide, aluminum oxide, and/or lithium carbonate.

Other exemplary embodiments of the present invention relate to a composition for solar cell electrodes, which may include (A) about 60% by weight (wt %) to about 90 wt % of a conductive powder; (B) about 1 wt % to about 10 wt % of the glass frit; and (C) about 5 wt % to about 30 wt % of an organic vehicle.

The conductive powder (A) may include at least one of silver (Ag), gold (Au), palladium (Pd), platinum (Pt), copper (Cu), chromium (Cr), cobalt (Co), aluminum (Al), tin (Sn), lead (Pb), zinc (Zn), iron (Fe), iridium (Ir), osmium (Os), rhodium (Rh), tungsten (W), molybdenum (Mo), nickel (Ni), and/or indium tin oxide (ITO).

The glass frit (B) may have an average particle diameter (D50) from about 0.1 μm to about 5 μm.

The composition may further include at least one additive of dispersants, thixotropic agents, plasticizers, viscosity stabilizers, anti-foaming agents, pigments, UV stabilizers, antioxidants, and/or coupling agents.

Other exemplary embodiments of the present invention relate to an electrode formed using the composition for solar cell electrodes. The electrode may be a front electrode formed on an n-type substrate.

### BRIEF DESCRIPTION OF THE DRAWINGS

FIG. 1 illustrates a cooling curve, which is a DTA profile obtained by TG-DTA analysis using a mixture of the glass frit in Preparative Example 1 and aluminum (Al) powder in a weight ratio of 1:1.

FIG. 2 illustrates a cooling curve, which is a DTA profile obtained by TG-DTA analysis using a mixture of the glass frit in Preparative Example 2 and aluminum (Al) powder in a weight ratio of 1:1.

FIG. 3 illustrates a cooling curve, which is a DTA profile obtained by TG-DTA analysis using a mixture of the glass frit in Preparative Example 3 and aluminum (Al) powder in a weight ratio of 1:1.

FIG. 4 illustrates a cooling curve, which is a DTA profile obtained by TG-DTA analysis using a mixture of the glass frit in Preparative Example 4 and aluminum (Al) powder in a weight ratio of 1:1.

FIG. 5 illustrates a cooling curve, which is a DTA profile obtained by TG-DTA analysis using a mixture of the glass frit in Preparative Example 5 and aluminum (Al) powder in a weight ratio of 1:1.

FIG. 6 illustrates a cooling curve, which is a DTA profile obtained by TG-DTA analysis using a mixture of the glass frit in Preparative Example 6 and aluminum (Al) powder in a weight ratio of 1:1.

FIG. 7 illustrates a schematic view of a solar cell in accordance with one embodiment of the present invention.

### DETAILED DESCRIPTION

Exemplary embodiments now will be described more fully hereinafter in the following detailed description with reference to the accompanying drawings, in which some, but not all embodiments of the invention are described. Indeed, this invention may be embodied in many different forms and should not be construed as limited to the embodiments set forth herein; rather, these embodiments are provided so that this disclosure will satisfy applicable legal requirements. In the drawing figures, the dimensions of layers and regions may be exaggerated for clarity of illustration. Like reference numerals refer to like elements throughout.

Glass Frit

The glass frit can serve to enhance adhesion between the conductive powder and the wafer or the substrate and to form silver crystal grains in an emitter region by etching an anti-reflection layer and melting the silver powder so as to reduce contact resistance during the baking process of the composition for electrodes. Further, during the baking process, the glass frit softens and decreases the baking temperature.

In one embodiment, the glass frit includes lead oxide and boron oxide. The glass frit may further include at least one other agent, such as an oxide and/or carbonate that is different from the lead oxide and the boron oxide. Examples of the other optional agent may include without limitation tellurium oxide, bismuth oxide, silicon oxide, zinc oxide, tungsten oxide, magnesium oxide, strontium oxide, molybdenum oxide, barium oxide, nickel oxide, copper oxide, sodium oxide, cesium oxide, titanium oxide, tin oxide, indium oxide, vanadium oxide, cobalt oxide, zirconium oxide, aluminum oxide, and/or lithium carbonate.

The glass frit may include about 40 wt % to about 90 wt % of lead oxide (PbO) and about 6 wt % to about 50 wt % of boron oxide (B₂O₃) based on the total weight of the glass frit. In some embodiments, the glass frit may include lead oxide in an amount of about 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of lead oxide can be in a range from about any of the foregoing amounts to about any other of the foregoing amounts.

In some embodiments, the glass frit may include boron oxide in an amount of about 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 wt %. Further, according to some embodiments of the present invention, the amount of boron oxide can be in a range from about any of the foregoing amounts to about any other of the foregoing amounts.

In some embodiments, the glass frit may include the other optional agent in an amount of 0 (the agent is not present), about 0 (the agent is present), 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, or 43 wt %. Further, according to some embodiments of the present invention, the amount of the other agent can be in a range from about any of the foregoing amounts to about any other of the foregoing amounts.

In one embodiment, the lead oxide (PbO) may be present in an amount of about 50 wt % to about 85 wt %, for example, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, or 85 wt % based on the total weight of the glass frit.

In one embodiment, the boron oxide (B₂O₃) may be present in an amount of about 7 wt % to about 30 wt %, for example, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt % based on the total weight of the glass frit.

In one embodiment, the glass frit may include about 50% wt % to about 85 wt % of lead oxide (PbO), about 7 wt % to about 30 wt % of boron oxide (B₂O₃), and about 0 wt % to about 43 wt % of tellurium oxide (Te02).

In another embodiment, the glass frit may include about 50% wt % to about 85 wt % of lead oxide (PbO), about 7 wt % to about 30 wt % of boron oxide (B₂O₃), and about 0 wt % to about 43 wt % of silicon oxide (SiO₂).

In still another embodiment, the glass frit may include about 50% wt % to about 85 wt % of lead oxide (PbO), about 7 wt % to about 30 wt % of boron oxide (B₂O₃), about 0 wt % to about 40 wt % of tellurium oxide (TeO₂), and about 0 wt % to about 40 wt % of silicon oxide (SiO₂).

The glass frit may include lead oxide (PbO) and boron oxide (B₂O₃) in a weight ratio of lead oxide to boron oxide of about 1:0.075 to about 1:1. Within this range, the glass frit can secure p-n junction stability given varying surface resistances and can minimize contact resistance.

In one embodiment, the glass frit may include lead oxide and boron oxide in a weight ratio of lead oxide to boron oxide of about 1:0.08 to about 1:0.8, for example, 1:0.09, 1:0.1, 1:0.2, 1:0.3, 1:0.4, 1:0.5, 1:0.6, 1:0.7, or 1:0.8.

The glass frit may be prepared from the above metal oxides by any typical method known in the art. For example, the metal oxides may be mixed in a predetermined ratio. Mixing may be carried out using a ball mill or a planetary mill. The mixture may be melted at about 900° C. to about 1300° C., followed by quenching to about 25° C. The obtained resultant may be subjected to pulverization under a disk mill, a planetary mill, or the like, thereby preparing a glass frit.

The glass frit may have an average particle diameter (D50) from about 0.1 μm to about 5 μm, for example, from about 0.5 μm to about 3 μm. Within this range, the glass frit may neither obstruct deep curing by UV irradiation nor cause pinhole failure, which can occur in a developing process in fabrication of electrodes.

The average particle diameter of the glass frit may be measured using, for example, a Model 1064D (CILAS Co., Ltd.) after dispersing the glass frit in isopropyl alcohol (IPA) at room temperature for 3 minutes via ultrasonication.

A mixture of the glass frit and aluminum (Al) powder in a weight ratio of about 1:1 exhibits a phase transition peak, at which an Al crystallite is formed in a DTA profile, in the range from about 250° C. to about 650° C. in TG-DTA analysis.

In a first embodiment, a mixture of the glass frit and the aluminum (Al) powder exhibits a phase transition peak in the range of about 400° C. to about 650° C. in TG-DTA analysis. The mixture may be prepared by mixing the glass frit and the aluminum (Al) powder in a weight ratio of about 1:1. The phase transition peak may be obtained by heating the mixture to 900° C. at a heating rate of 20° C./min, holding for ten minutes, followed by cooling the mixture at a cooling rate of 10° C./min. While the mixture is cooled at the cooling rate of 10° C./min, the phase transition peak temperature, at which an Al crystallite is formed, is measured via TG-DTA analysis.

In a second embodiment, the mixture of the glass frit and the aluminum (Al) powder in a weight ratio of about 1:1 may exhibit a phase transition peak in the range of about 250° C. to about 300° C. in TG-DTA analysis. The phase transition peak may be obtained by heating the mixture to 600° C. at a heating rate of 20° C./min, holding for ten minutes, followed by cooling the mixture at a cooling rate of 10° C./min, the phase transition peak temperature, at which an Al crystallite is formed, is measured via TG-DTA analysis.

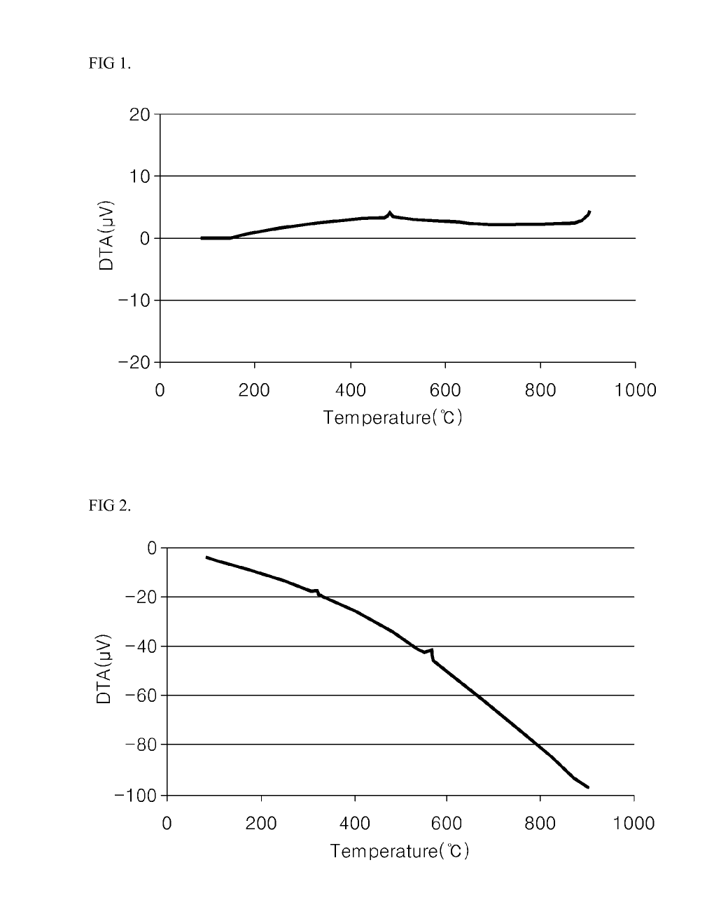

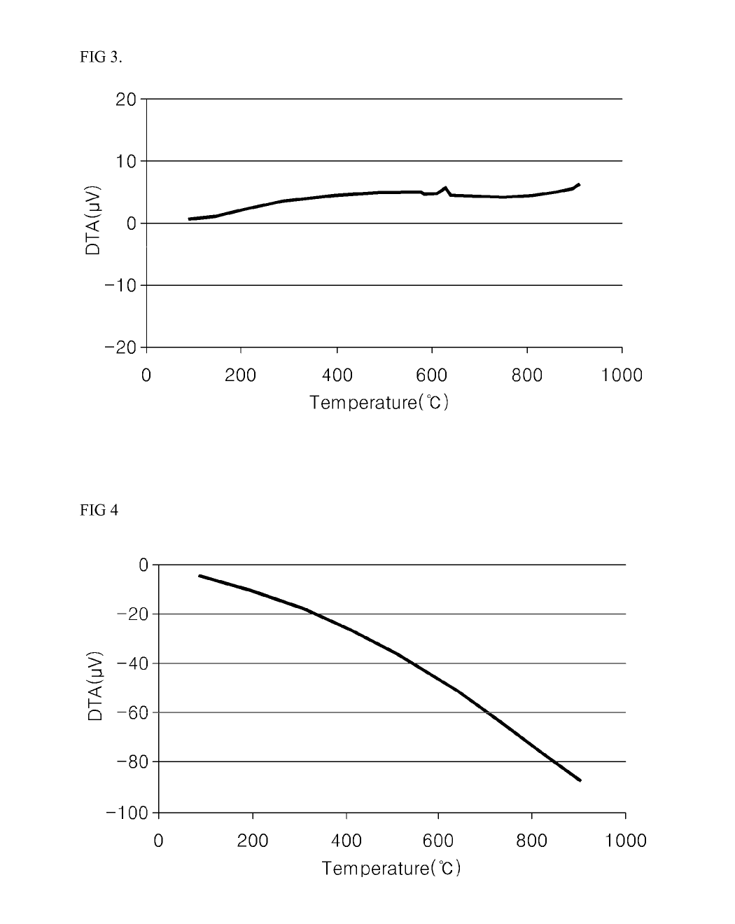

FIGS. 1 to 3 illustrate a cooling curve, which is a DTA profiles obtained by TG-DTA analyses using a mixture of the respective glass frit prepared in Preparative Examples 1 to 3 and aluminum (Al) powder in a weight ratio of 1:1. Referring to FIGS. 1 to 3, the mixture of the glass frit according to the present invention and aluminum (Al) powder in a weight ratio of 1:1 has a phase transition peak, at which an Al crystallite is formed, within a range from 250° C. to 650° C. on a cooling curve in TG-DTA analysis.

Composition for Solar Cell Electrodes

A composition for solar cell electrodes according to the invention may include a conductive powder (A); a glass frit (B); an organic vehicle (C); and additives (D).

(A) Conductive Powder

Examples of the conductive powder may include silver (Ag), gold (Au), palladium (Pd), platinum (Pt), copper (Cu), chromium (Cr), cobalt (Co), aluminum (Al), tin (Sn), lead (Pb), zinc (Zn), iron (Fe), iridium (Ir), osmium (Os), rhodium (Rh), tungsten (W), molybdenum (Mo), nickel (Ni), and/or magnesium (Mg) powder, without being limited thereto. These conductive powders may be used alone or as a mixture or alloy of two or more thereof For example, the conductive powder may include silver powder alone. In some embodiments, the conductive powder may further include aluminum (Al), nickel (Ni), cobalt (Co), iron (Fe), zinc (Zn), or copper (Cu) powder in addition to the silver powder. In one embodiment, the conductive powder may include about 85 wt % to about 100 wt % of silver powder and about 0 wt % to about 15 wt % of aluminum powder.

The conductive powder may have a spherical, flake and/or amorphous particle shape.

The conductive powder may be a mixture of conductive powders having different particle shapes.

The conductive powder may have an average particle size (D50) of about 0.1 μm to about 5 μm, for example, about 0.5 μm to about 2 μm. The average particle size may be measured using, for example, a Model 1064D particle size analyzer (CILAS Co., Ltd.) after dispersing the conductive powder in isopropyl alcohol (IPA) at 25° C. for 3 minutes via ultrasonication. Within this range of average particle size, the paste composition can provide low contact resistance and line resistance.

The conductive powder may be a mixture of conductive particles having different average particle sizes (D50).

The composition for solar cell electrodes may include the conductive powder in an amount of about 60 wt % to about 90 wt %, for example, about 70 wt % to about 88 wt %, based on the total weight (100 wt %) of the composition for solar cell electrodes. In some embodiments, the composition for solar cell electrodes may include conductive powder in an amount of about 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of conductive powder can be in a range from about any of the foregoing amounts to about any other of the foregoing amounts.

Within this range, the conductive powder may prevent deterioration in conversion efficiency of a solar cell due to resistance increase and difficulty in forming the paste due to relative reduction in amount of the organic vehicle.

(B) Glass Frit

The glass frit, as described above, may be present in an amount of about 1 wt % to about 10 wt % based on the total weight (100 wt %) of the composition for solar cell electrodes. For example, the glass frit may be present in an amount of about 1 wt % to about 7 wt %. In some embodiments, the composition for solar cell electrodes may include the glass frit in an amount of about 1, 2, 3, 4, 5, 6, 7, 8, 9, or 10 wt %. Further, according to some embodiments of the present invention, the amount of glass frit can be in a range from about any of the foregoing amounts to about any other of the foregoing amounts.

Within this range, it is possible to improve sintering properties and adhesion of the conductive powder while preventing deterioration in conversion efficiency due to resistance increase. Further, it is possible to prevent an excess of the glass frit from remaining after baking, which can cause increase in resistance and deterioration in solderability.

Since the glass frit can exhibit sufficient thermal stability to withstand a wide range of baking temperatures, it is possible to form electrodes on surfaces of wafers having different sheet resistances using the composition for solar cell electrodes including the glass frit.

(C) Organic Vehicle

The organic vehicle may include an organic binder that provides liquidity to the composition for solar cell electrodes.

Examples of the organic binder may include cellulose polymers, such as ethylcellulose, hydroxyethylcellulose, hydroxypropylcellulose, hydroxyethylhydroxypropylcellulose, and the like; acrylic copolymers obtained by copolymerization with hydrophilic acrylic monomers such as carboxyl groups; polyvinyl resins; and the like, without being limited thereto. These binders may be used alone or as a mixture thereof

The organic vehicle may further include a solvent. In this case, the organic vehicle may be a solution prepared by dissolving the organic binder in the solvent.

The organic vehicle may include about 5 wt % to about 40 wt % of the organic binder and about 60 wt % to about 95 wt % of the solvent. For example, the organic vehicle may include about 6 wt % to about 30 wt % of the organic binder and about 70 wt % to about 94 wt % of the solvent.

In some embodiments, the organic vehicle may include the organic binder in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40 wt %. Further, according to some embodiments of the present invention, the amount of organic binder can be in a range from about any of the foregoing amounts to about any other of the foregoing amounts.

In some embodiments, the organic vehicle may include the solvent in an amount of about 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, or 95 wt %. Further, according to some embodiments of the present invention, the amount of solvent can be in a range from about any of the foregoing amounts to about any other of the foregoing amounts.

The solvent may be an organic solvent having a boiling point of about 120° C. or more. Examples of the solvent may include without limitation carbitol solvents, aliphatic alcohols, ester solvents, cellosolve solvents, and/or hydrocarbon solvents, which may be commonly used in the production of electrodes. Examples of solvents suitable for use in the paste composition may include without limitation butyl carbitol, butyl carbitol acetate, methyl cellosolve, ethyl cellosolve, butyl cellosolve, aliphatic alcohols, terpineol, ethylene glycol, ethylene glycol monobutyl ether, butyl cellosolve acetate, Texanol, and the like, and mixtures thereof.

The composition for solar cell electrodes may include the organic vehicle in an amount of about 5 wt % to about 30 wt % based on the total weight (100 wt %) of the composition for solar cell electrodes. For example, the organic vehicle may be present in an amount of about 10 wt % to about 25 wt %. In some embodiments, the composition for solar cell electrodes may include the organic vehicle in an amount of about 5, 6, 7, 8, 9, 10, 11, 12, 13, 14, 15, 16, 17, 18, 19, 20, 21, 22, 23, 24, 25, 26, 27, 28, 29, or 30 wt %. Further, according to some embodiments of the present invention, the amount of the organic vehicle can be in a range from about any of the foregoing amounts to about any other of the foregoing amounts.

Within this range, it is possible to prevent inefficient dispersion or excessive increase in viscosity after preparation of the composition, which can lead to printing difficulty, and to prevent resistance increase and other problems that can occur during the baking process.

(D) Additives

The composition may further include one or more typical additives to enhance fluidity, process properties, and/or stability, as needed. Examples of the additives may include without limitation dispersants, thixotropic agents, plasticizers, viscosity stabilizers, anti-foaming agents, pigments, UV stabilizers, antioxidants, and/or coupling agents. These additives may be used alone or as a mixture thereof These additives may be present in an amount of about 0.1 wt % to about 5 wt % based on the total weight (100 wt %) of the composition, without being limited thereto.

Solar Cell Electrode and Solar Cell Including the Same

Other exemplary embodiment of the invention relate to an electrode formed of the composition for solar cell electrodes and a solar cell including the same. The electrode formed of the composition for solar cell electrodes can minimize adverse influence on a p-n junction given varying substrates, such as p-type and/or n-type substrates to reduce contact resistance, thereby improving solar cell efficiency.

In one embodiment, the composition for solar cell electrodes may be used for a p+ electrode and/or for an n-type electrode that may be formed on an n-type substrate doped with group III elements, such as boron (B), gallium (Ga), indium (In), and the like. For example, the composition for solar cell electrodes may be used for a front electrode.

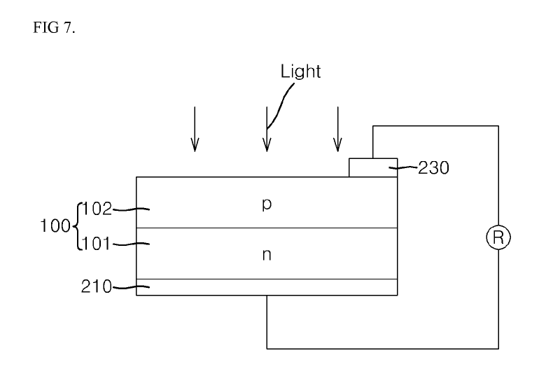

FIG. 7 illustrates a solar cell in accordance with one embodiment of the invention.

Referring to FIG. 7, a rear electrode 210 and a front electrode 230 may be formed by printing and baking the composition on a wafer or substrate 100 that may include an p-layer 101 and a p-layer 102, which will serve as an emitter.

For example, a preliminary process for preparing the rear electrode 210 may be performed by printing the composition on the rear surface of the wafer 100 and drying the printed composition at about 200° C. to about 400° C. for about 10 to about 60 seconds. Further, a preliminary process for preparing the front electrode may be performed by printing the paste on the front surface of the wafer and drying the printed composition. Then, the front electrode 230 and the rear electrode 210 may be formed by baking the wafer at about 400° C. to about 950° C., for example at about 850° C. to about 950° C., for about 30 to about 50 seconds.

Next, the present invention will be described in more detail with reference to the following examples. However, it should be understood that these examples are provided for illustration only and should not be construed in any way as limiting the invention.

A description of details apparent to those skilled in the art will be omitted.

### EXAMPLES

### Preparative Examples 1 to 7: Preparation of Glass Frit

Metal oxides are mixed in compositions (unit: wt %) as listed in Table 1. The mixture is melted at 1000° C., followed by quenching to 25° C. The obtained resultant is subjected to pulverization under a disk mill, thereby preparing glass frits (GF1 to GF7) having an average particle diameter of 2 μm.

TG-DTA Analysis of Glass Frit

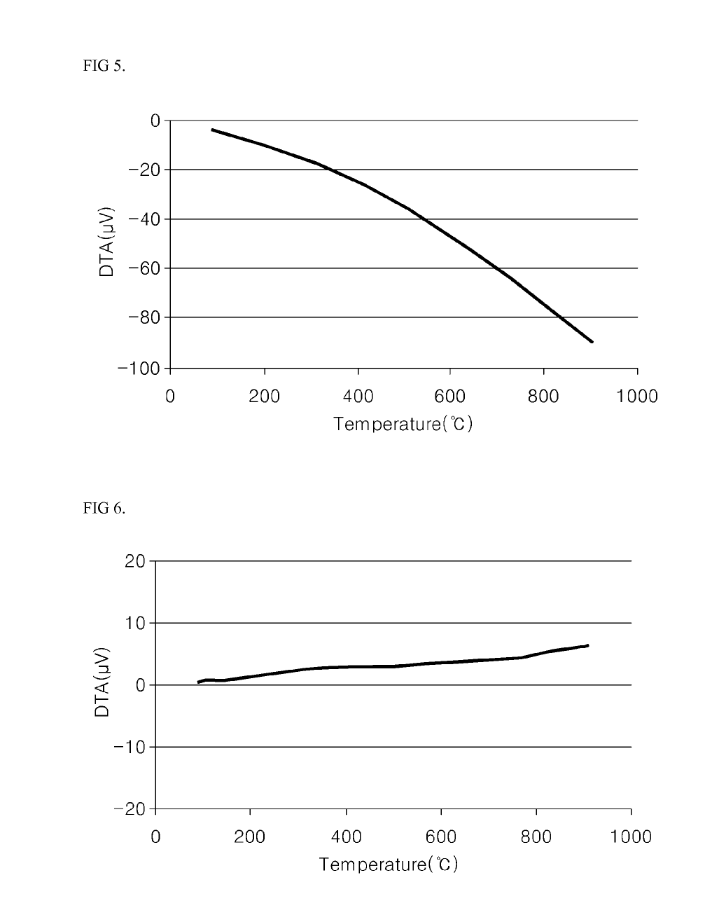

Phase transition temperature I: The prepared glass frits (GF1 to GF7) are mixed with aluminum (Al) powder (Yuanyang Co., Ltd., D50=3 μm) in a weight ratio of 1:1. The resulting mixture is heated to 900° C. at a heating rate of 20° C./min using an alumina pan P/N SSC515D011 and EXSTAR 6200 (EXSTAR Co., Ltd.) and held there for a wait-time of ten minutes. While the mixture is cooled at a cooling rate of 10° C./min, TG-DTA analysis is carried out. Cooling curves, which are DTA profiles of Examples 1 to 6, are shown in FIGS. 1 to 6, respectively. Further, a phase transition peak temperature, at which an Al crystallite is formed, is measured via TG-DTA analysis. Measurement results are shown in Table 1.

Phase transition temperature II: The prepared glass frits are mixed with aluminum (Al) powder (Yuanyang Co., Ltd., D50=3 μm) in a weight ratio of 1:1. The resulting mixture is heated to 600° C. at a heating rate of 20° C./min using an alumina pan P/N SSC515D011 and an EXSTAR 6200 (EXSTAR Co., Ltd.), followed by a wait time of ten minutes. While the mixture is cooled at a cooling rate of 10° C./min, a phase transition peak temperature, at which an Al crystallite is formed, is measured via TG-DTA analysis. Measurement results are shown in Table 1.

TABLE 1

| | | Preparative | Preparative | Preparative | Preparative | Preparative | Preparative | Preparative |
|---|---|---|---|---|---|---|---|---|
| | | Example 1 | Example 2 | Example 3 | Example 4 | Example 5 | Example 6 | Example 7 |
| | | GF 1 | GF 2 | GF 3 | GF 4 | GF 5 | GF 6 | GF 7 |
| Composition | PbO | 83 | 77 | 70 | 50 | 60 | 80 | — |
| of glass frit | B₂O₃ | 7 | 23 | 10 | — | 5 | — | — |
| (wt %) | TeO₂ | — | — | 10 | 40 | 15 | — | — |
| | Bi₂O₃ | — | — | — | 10 | — | — | — |
| | ZnO | — | — | — | — | 5 | 5 | — |
| | Al₂O₃ | — | — | — | — | — | — | 100 |
| | SiO₂ | 10 | — | 10 | — | 15 | 15 | — |
| TG-DTA | Al powder | 50 | 50 | 50 | 50 | 50 | 50 | 50 |
| analysis | (wt %) | | | | | | | |
| | Glass frit | 50 | 50 | 50 | 50 | 50 | 50 | 50 |
| | (wt %) | | | | | | | |
| | Phase | 494 | 567 | 626 | — | — | — | — |
| | transition | | | | | | | |
| | temperature | | | | | | | |
| | I° C. | | | | | | | |
| | Phase | 280 | 269 | 273 | — | — | — | — |
| | transition | | | | | | | |
| | temperature | | | | | | | |
| | II° C. | | | | | | | |

### Example 1

2 wt % of aluminum powder (Yuanyang Co., Ltd., D50=3 μm), 85 wt % of silver powder (Dowa 5-11F, Dowa Hightech Co., Ltd.), and 10.5 wt % of an organic binder are added to 2.5 wt % of the glass frit (GF1) in Preparative Example 1, followed by mixing and kneading in a 3-roll kneader, thereby preparing a composition for solar cell electrodes.

### Examples 2 to 3 & Comparative Examples 1 to 4

Compositions for solar cell electrodes are prepared in the same manner as in Example 1 except that the glass frits (GF2 to GF7) in Preparative Examples 2 to 7 are used, respectively.

Property Evaluation (Transfer Length Method)

Each of the compositions for solar cell electrodes prepared in Examples 1 to 3 and Comparative Examples 1 to 4 is printed on a front side of a boron-doped n-type substrate (70 Ω, a mono-crystalline wafer) in TLM (Transfer Length Method) patterns (50 μm in width, 0.6 cm in length, 2 mm to 10 mm in distance between patterns (increased by 2 mm)) The printed wafer is dried and subjected to baking at 900° C. for 30 seconds. After baking, 5 resistance values are measured, and the measured values are plotted to obtain contact resistance (Rc) values, which represent ½ y-intercept values. Results are shown in Table 2.

TABLE 2

| | | | | Comp. | Comp. | Comp. | Comp. |
|---|---|---|---|---|---|---|---|
| | Example 1 | Example 2 | Example 3 | Example 1 | Example 2 | Example 3 | Example 4 |
| Glass frit | GF 1 | GF2 | GF3 | GF4 | GF5 | GF6 | GF7 |
| Contact | 0.3 | 0.1 | 0.8 | 5.6 | 4.8 | 4.0 | — |
| resistance (Ω) | | | | | | | |

As shown in Table 2, it can be seen that the compositions of Examples 1 to 3 using glass frits GF1 to GF3 respectively have much lower contact resistance than the compositions of Comparative Examples 1 to 3 using the glass frits GF4 to GF6 respectively. Here, the glass frits GF1 to GF3 have phase transition temperatures I and II in the range as set forth above on a cooling curve in TG-DTA analysis using a mixture of the glass frit and aluminum (Al) powder, whereas the glass frits GF4 to GF6 used in Comparative Examples 1 to 3 did not exhibit the phase transition temperature I or II.

Many modifications and other embodiments of the invention will come to mind to one skilled in the art to which this invention pertains having the benefit of the teachings presented in the foregoing description. Therefore, it is to be understood that the invention is not to be limited to the specific embodiments disclosed and that modifications and other embodiments are intended to be included within the scope of the appended claims.

1. A glass frit comprising:
lead oxide (PbO) and boron oxide (B₂O₃) in a weight ratio of lead oxide to boron oxide of about 1:0.075 to about 1:1,
wherein a mixture of the glass frit and aluminum (Al) powder in a weight ratio of about 1:1 exhibits a phase transition peak in the range of about 400° C. to about 650° C. on a cooling curve obtained via TG-DTA analysis, measured after heating the mixture to 900° C. at a heating rate of 20° C./min, holding for ten minutes, followed by cooling the mixture at a cooling rate of 10° C./min.

2. The glass frit according to claim 1, wherein the mixture exhibits a phase transition peak in the range of about 250° C. to about 300° C. on a cooling curve obtained via TG-DTA analysis, measured after heating the mixture to 600° C. at a heating rate of 20° C./min, holding for ten minutes, followed by cooling the mixture at a cooling rate of 10° C. /min.

3. The glass frit according to claim 1, wherein the glass frit further comprises: at least one of bismuth oxide, silicon oxide, zinc oxide, lead oxide, tellurium oxide, tungsten oxide, magnesium oxide, strontium oxide, molybdenum oxide, barium oxide, nickel oxide, copper oxide, sodium oxide, cesium oxide, titanium oxide, tin oxide, indium oxide, vanadium oxide, cobalt oxide, zirconium oxide, aluminum oxide, and lithium carbonate.

4. A composition for solar cell electrodes, comprising: (A) about 60 wt % to about 90 wt % of a conductive powder; (B) about 1 wt % to about 10 wt % of the glass frit according to any one of claims 1 to 3; and (C) about 5 wt % to about 30 wt % of an organic vehicle.

5. The composition according to claim 4, wherein the conductive powder comprises at least one of silver (Ag), gold (Au), palladium (Pd), platinum (Pt), copper (Cu), chromium (Cr), cobalt (Co), aluminum (Al), tin (Sn), lead (Pb), zinc (Zn), iron (Fe), iridium (Ir), osmium (Os), rhodium (Rh), tungsten (W), molybdenum (Mo), nickel (Ni), and indium tin oxide (ITO) powders.

6. The composition according to claim 4, wherein the glass frit has an average particle diameter (D50) from about 0.1 μm to about 5 μm.

7. The composition according to claim 4, further comprising: (D) at least one additive of dispersants, thixotropic agents, plasticizers, viscosity stabilizers, anti-foaming agents, pigments, UV stabilizers, antioxidants, and coupling agents.

8. A solar cell electrode prepared from the composition for solar cell electrodes according to claim 4.

9. The solar cell electrode according to claim 8, wherein the solar cell electrode is a front electrode formed on an n-type substrate.
